(19) United States
(12) Patent Application Publication
(10) Pub. No.: US 2024/0107764 A1
(43) Pub. Date: Mar. 28, 2024

(54) INTEGRATION APPROACH FOR INCREASE OF THE MOBILITY AND ON-CURRENT IN 3D NAND CELLS

(71) Applicant: Applied Materials, Inc., Santa Clara, CA (US)

(72) Inventor: Milan PESIC, Paoli, PA (US)

(21) Appl. No.: 18/243,085

(22) Filed: Sep. 6, 2023

Related U.S. Application Data
(60) Provisional application No. 63/409,036, filed on Sep. 22, 2022.

(51) Int. Cl. H10B 43/27; H10B 41/27

(52) U.S. Cl. CPC H10B 43/27; H10B 41/27

(57) ABSTRACT

Embodiments of the disclosure provided herein include an apparatus for and method of forming an improved three-dimension (3D) memory structure/cell that includes a channel that includes polysilicon channel that has been processed to passivate and remove defects found in the channel structure of a 3D memory device, such as a 3D NAND device. In some embodiments, the processing performed on the channel structure utilizes the deposition of a fluorine containing layer that includes a concentration of fluorine (F) atoms that are then driven into a polysilicon channel layer using at least one anneal step that is performed in a hydrogen or deuterium containing environment to load the polysilicon layer with fluorine (F) and hydrogen (H) atoms.

### CROSS-REFERENCE TO RELATED APPLICATIONS

This application claims priority to U.S. Provisional patent application Ser. No. 63/409,036, filed Sep. 22, 2022, which is herein incorporated by reference.

### BACKGROUND

### Field

The present disclosure generally relates to memory devices, and methods of manufacturing the same, and more particularly, to device structures and methods of forming three-dimensional (3D) memory devices.

### Description of the Related Art

Memory devices are an essential component in digital electronic devices that are being developed today. With the increase in technology today, there is a need for increased memory capacity in most electronic devices. At the same time there is also a need for smaller memory devices to meet the market place's desire to create smaller electronic devices in which the memory device is positioned within.

In recent years, conventional (2D) NAND memory devices have run into a number of challenges, including voltage drop related issues (e.g., running out of electrons in the current carrying elements due to the ever scaling of the cell size), retention loss and overall reliability. To address these challenges encountered in scaling planar (2D) NAND memory devices to achieve higher densities at a lower cost per bit, ultra-high density, three-dimensional (3D) stacked memory structures have been introduced. Such 3D memory structures are sometimes referred to as having a Bit Cost Scalable (BiCS) architecture, and include strings of vertically integrated memory cells. Typically, the vertically aligned memory cells are formed from an array of alternating conductor and insulator layers, where the conductive layers correspond to the word lines of the memory structure.

As the number of vertically stacked memory cells in 3D NAND devices increases (e.g., as chip densities increase), the resistivity of the memory cell string (e.g., channel structure) also increases, introducing numerous performance issues. As resistivity increases, more advanced circuits are required for current sensing. Typically, the memory cell string may include a number of word line layers. As the number of vertically stacked layers increase, the overall resistance of the vertically oriented channel structure of the 3D NAND memory increases, leading to a drop in the amount of current that can (1) flow in the channel structure and most importantly (2) be detected at by the sense amplifier. Based on the current design rules and pitches, at around 500 stacked word line layers, it may not be possible to detect any current flowing through the channel structure which corresponds to the stored state. In turn, difference between stored states would be indistinguishable. Currently, it is common to utilize a polysilicon channel in the channel structure of a 3D NAND device. As a result of the use of a polysilicon channel and its highly granular nature, the 3D NAND device may be suffer from reduced mobility, ON current degradation, increased device variability, as well as retention degradation. In past a macaroni type 3D NAND device were suggested and implemented that comprise off the filler oxide which minimizes the thickness of the polysilicon channel and in turn reduce the number of grain boundaries (GBs) responsible for the electron scattering and improve the ON current. Even though the number of GBs is reduced in this approach, they are still present and cannot overcome the 500 WL stacking limit.

Therefore, there is a need for an improved memory device structure and method of forming the same that solves the problems described above.

### SUMMARY

Embodiments of the disclosure may include a three-dimensional memory device, comprising: a plurality of alternating layers formed over a surface of a substrate, wherein the alternating layers comprises a word line layer and an inter-word line dielectric layer that are stacked in a first direction; a gate coupled to each of the word line layers of the plurality of alternating layers; a polysilicon channel layer having a first end coupled to a source region, a second end coupled to a drain region, and extending in the first direction between the source region and the drain region; and an ONO layer stack disposed between the gate and the polysilicon layer, wherein the ONO layer stack extends in the first direction between the source region and the drain region. The polysilicon channel layer may comprise a polysilicon layer that comprises a fluorine (F) concentration >1×10¹⁴ atoms/cm³ and a hydrogen (H) concertation of >1×10¹⁴ atoms/cm³.

Embodiments of the disclosure may further include a method of forming a three-dimensional memory device, comprising: forming a channel structure within a plurality of openings formed through a plurality of alternating layers formed over a surface of a substrate, comprising: forming a ONO layer stack over a surface of each of the plurality of openings; and forming a polysilicon layer over a surface of the ONO layer stack; forming a fluorine containing layer on the formed polysilicon layer; annealing the substrate, wherein annealing the substrate causes fluorine atoms originally disposed in the fluorine containing layer to diffuse into the polysilicon layer; and selectively removing the fluorine containing layer; annealing the substrate in a hydrogen containing environment to cause the hydrogen atoms from the hydrogen containing environment to diffuse into the polysilicon layer; and forming a drain region layer over the plurality of alternating layers, wherein at least a portion of the formed channel structure is coupled to a portion of the drain region layer and coupled to a portion of a source region layer of the three-dimensional memory device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a simplified schematic example of a three-dimensional (3D) NAND memory structure 100.

FIG. 2 illustrates a method 200 of forming a channel structure within a 3D NAND memory structure, according to one or more of the embodiments described herein.

FIGS. 3A, 3B, 3C, 3D, 3E, 3F, 3G, and 3H are a schematic side cross-sectional views of a portion 301 of the 3D NAND memory structure that are used to illustrate the activities performed in the method 200, according to one or more of the embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments of the disclosure provided herein include an apparatus for and method of forming an improved three-dimension (3D) memory structure/cell that includes a multi-layer channel that includes polysilicon channel that has been processed to passivate and remove defects found in the channel structure of a 3D memory device, such as a 3D NAND device. In some embodiments, the processing performed on the channel structure utilizes the deposition of a fluorine containing amorphous silicon (aSi) that includes a concentration of fluorine (F) atoms that are then driven into a polysilicon channel layer using at least one anneal step that is performed in a hydrogen (H₂) or a deuterium (D₂) containing environment to load the polysilicon layer with fluorine (F) and hydrogen (H) atoms. The modified polysilicon channel described herein has been found to provide a higher “On” currents, through the use of the modified polysilicon layer during operation. It is believed that the process of modifying the polysilicon layer will reduce the defects and electron scattering centers which will increase the electron mobility in the channel layer, which will help to increase the speed and reliability of the 3D NAND device due to a higher magnitude of the current that can be conducted through the channel structure of the device. As a consequence of the modification of the polysilicon channel, the channel structure and whole memory string exhibit a decreased resistance and variability. As a result, the modified polysilicon channel in the channel structure may enable a greater number of word lines (e.g., more than 500 word lines) in the 3D memory structure.

Embodiments disclosed herein can be useful for, but are not limited to, channel structures in two dimensional (2D) and 3D memory.

### 3D NAND Memory Device Structure

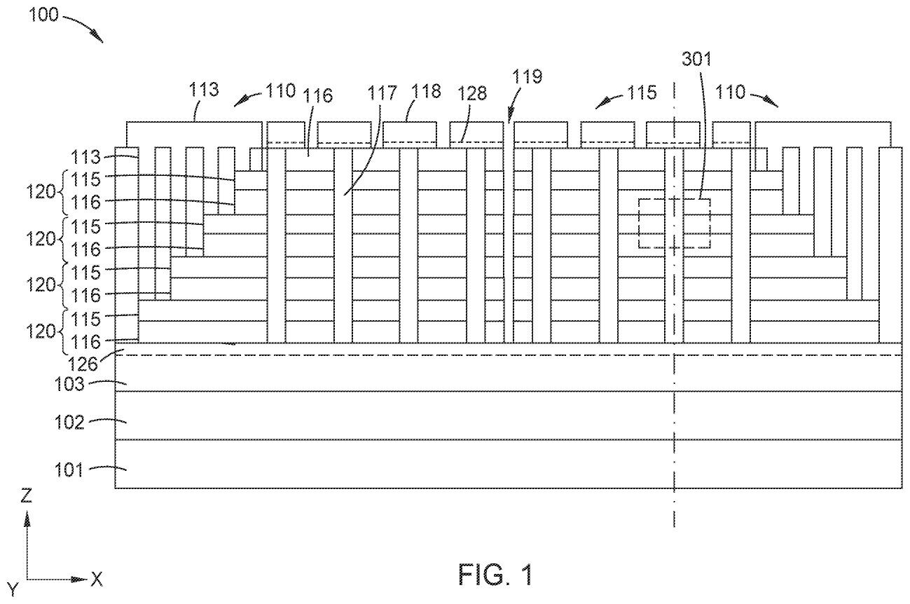

FIG. 1 is a simplified schematic example of a 3D NAND memory structure 100. The 3D NAND memory structure includes a channel structure 117 that is oriented in a vertical direction, such that the channel structure 117 is oriented perpendicular (e.g., Z-direction) to a major surface of the substrate 101 that includes an etch stop layer (ESL) 102 and a common source line layer (CSL) 103 disposed thereon. The top of the vertical channel layer structure 117 includes a plurality of bit lines 118. The stacked layers are configured in stacked layer pairs 120 that each include a dielectric layer 116 and a word line layer 115. In this configuration, the word line layers 115 (e.g., four layers shown in FIG. 1) are stacked in the direction that is perpendicular to the major surface of the substrate to form a string of memory cells and each include a portion of one of the channel layer structures 117. At an end of each word line layer 115 is a staircase-like structure 110. In the staircase-like structure 110, one or more conductive columns 114 are used to connect the word line layer 115 to an external control circuit by use of connecting element lines 113. In this way, in the 3D NAND memory structure, a memory cell may be fabricated in a vertical direction, so that a memory capacity may be easily increased by stacking additional layers. A gate slit line 119 may also be formed through the 3D NAND memory structure 100. It should be noted that, in some embodiments, the word line layer 115 is deposited later in the process of forming the 3D NAND device by removing a dummy (second) dielectric material (e.g., dummy nitride material) by use of an etching process and then depositing a conductive layer in same place where the dummy (second) dielectric material was positioned.

The 3D NAND memory structure 100 may also include a source region 126 (e.g., N+ source layer), which may be part of or formed on the CSL 103, and a drain region 128 (e.g., N+ drain layer), which may be part of or formed under the plurality of bit lines 118. The staircase-like structures 110, which are formed on two opposing edges of the 3D NAND memory structure 100, require a two-dimensional area (i.e., X-Z plane) to connect all of the word line layers 115 to external elements outside of the 3D NAND device.

### Channel Formation Process Examples

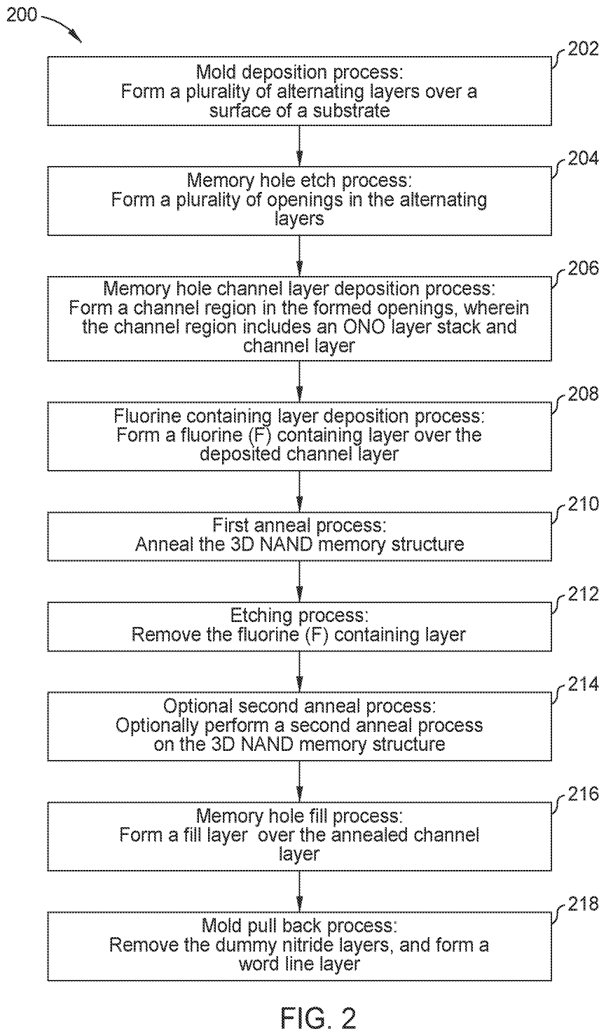

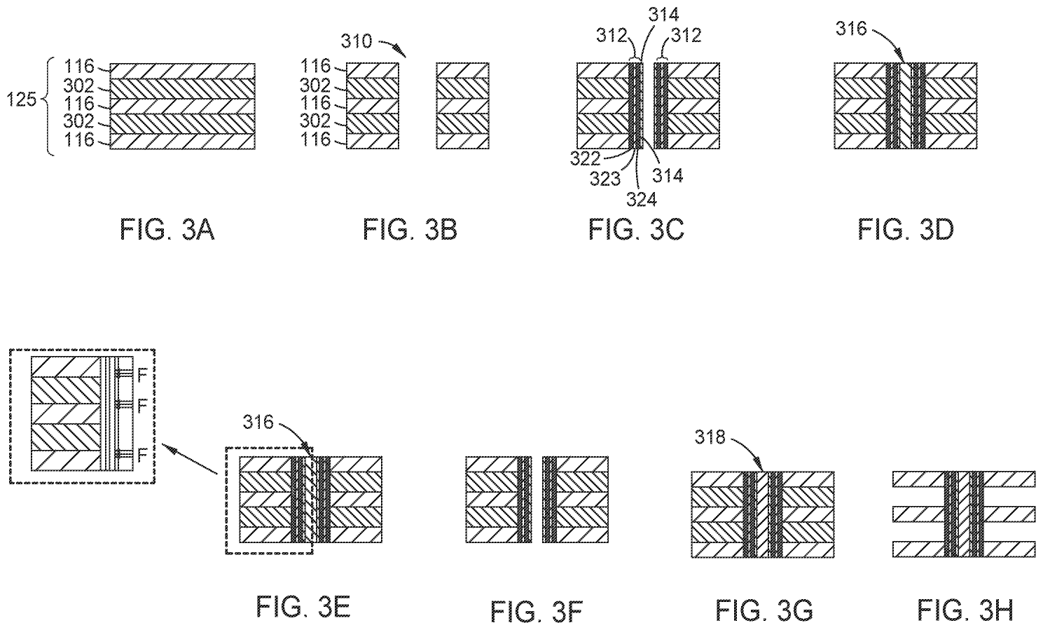

FIG. 2 illustrates a method 200 for use in the manufacturing of a 3D memory cell, such as forming a portion 301 of the 3D NAND memory structure 300, according to one or more of the embodiments described herein. FIGS. 3A, 3B, 3C, 3D, 3E, 3F, 3G, and 3H illustrate schematic side cross-sectional views of portions (e.g., 301) of the 3D NAND memory structure 300 during one or more of the activities illustrated in FIG. 2, according to one or more of the embodiments described herein. Therefore, FIG. 2 and FIGS. 3A, 3B, 3C, 3D, 3E, 3F, 3G, and 3H are herein described together for clarity.

The method 200 begins with a mold deposition process at activity 202, where a plurality of alternating layers 125 are formed over a surface of a substrate 101. In some embodiments, forming the plurality of alternating layers 125 may include forming a plurality of dummy nitride layers 302 and a plurality of inter-word line dielectric layers 116 that are sequentially stacked in a first direction (perpendicular to a major surface of the substrate 101, e.g., Z-direction) over a common source line layer (CSL) 103 that is disposed over the surface of the substrate 101. The portion 301 of the 3D NAND memory structure 300 is illustrated in FIG. 3A.

At activity 204, a memory hole etch process is performed, where a plurality of openings 310 (e.g., memory holes) extending in the first direction from the CSL 103 and through the plurality of alternating layers 125 are etched, as shown in FIG. 3B. The memory holes 310 may be etched using a high aspect ratio etching process. Further, the memory holes 310 extend from a CSL 103 through the plurality of alternating layers 125 in the first direction.

At activity 206, a memory hole channel layer deposition process is performed, where a channel structure 117 is formed within the memory holes 310. The process of forming the channel structure 117 includes depositing an oxide-nitride-oxide (ONO) layer stack 312 over the surface of each of the memory holes 310 in the portion 301 of the 3D NAND memory structure 100 by use of an atomic layer deposition (ALD) or chemical vapor deposition (CVD) process, as shown in FIG. 3C. Depositing the ONO layer stack 312 includes forming a first dielectric layer (e.g., a first oxide layer 322) over the surface of each of the memory holes 310 through the plurality of alternating layers 125 of the dummy nitride layer 302 and the dielectric layers 116. The process of depositing the first oxide layer 322 may include, for example, depositing a layer (e.g., a continuous layer) of aluminum oxide (Al₂O₃ or similar) and or silicon oxide (SiOₓ) on inner surfaces of each of the memory holes 310 (e.g., sides that define the plurality of openings formed in the plurality of alternating layers 125 and along the CSL 103 and/or the ESL102 at the bottom of the memory holes 310. The first oxide layers 322 are forming so-called barrier oxide and high-k layer of the memory cell. The process of depositing the ONO layer stack 312 also includes depositing a silicon nitride layer (e.g., a charge trap layer 323) on the first oxide layer 322 by use of an atomic layer deposition (ALD) or chemical vapor deposition (CVD) process, as shown in FIG. 3C. The charge trap layer 323 may include a layer of trap-silicon nitride (Si₃N₄), or even a polycrystalline silicon (poly-Si) layer (floating gate NAND cell architecture). The process of depositing the ONO layer stack 312 also includes forming a second dielectric layer (e.g., a second oxide layer 324) on the charge trap layer 323 by use of an atomic layer deposition (ALD), plasma enhanced ALD (PEALD), chemical vapor deposition (CVD) or plasma enhanced chemical vapor deposition (PECVD) process, as shown in FIG. 3C. The second oxide layer 324 may include a layer of silicon oxide (SiOₓ) or band-gap engineered combination of the SiO₂/SiN/SiO₂. The second oxide layer 324, or the combination of band-gap engineered layers, can be used to form a tunneling oxide region of the device. The first oxide layer 322, the charge trap layer 323, and the second oxide layer 324 altogether form the simplified ONO layer stack 312. The process of forming the channel structure 117 also includes depositing a channel layer 314 in the plurality of openings 310 on the second dielectric layer (e.g., a second oxide layer 324), by use of an atomic layer deposition (ALD) or chemical vapor deposition (CVD) process, as shown in FIG. 3C. For example, the channel layer 314 may be a polysilicon layer.

At activity 208, a fluorine containing layer deposition process is performed, where a fluorine (F) containing layer 316 is formed over the deposited channel layer 314 within the memory holes 310. The process of forming the fluorine (F) containing layer 316 includes depositing an fluorine (F) containing layer 316 over the surface of each of the memory holes 310 of the 3D NAND memory structure 100 by use of an atomic layer deposition (ALD), plasma enhanced ALD (PEALD), chemical vapor deposition (CVD) or plasma enhanced chemical vapor deposition (PECVD) process, as shown in FIG. 3D. In some embodiments, depositing the fluorine (F) containing layer 316 includes forming an amorphous silicon layer that includes a fluorine (F) concentration of about 5 at. %, on a sidewall of the channel layer 314 that is disposed on the ONO layer stack 312 on the plurality of alternating layers 125 of the dummy nitride layer 302 and the dielectric layers 116.

At activity 210, as shown in FIG. 3E, a first anneal process is performed on the 3D NAND memory structure 100 so that the mobile fluorine (F) atoms in the fluorine (F) containing layer 316 diffuse into the channel layer 314 and passivate the defects in the polysilicon material within the channel layer 314. The first anneal process can be a spike anneal or other similar process that is able to drive the fluorine (F) atoms into the channel layer 314. Typically, the concentration of fluorine atoms in the channel layer 314 after performing the first anneal process will be greater than 1×10¹⁴/cm³, or even greater than 1×10¹⁵/cm³. In one embodiment, the first anneal process includes a high pressure anneal process (e.g., 5 ATM) that is performed in a hydrogen (H₂) or deuterium (D₂) containing environment.

At activity 212, an etching process is performed to selectively remove the fluorine (F) containing layer 316, as shown in FIG. 3F. The etching process may be performed using a selective removal plasma (SRP) etching process available from Applied Materials Inc. of Santa Clara, CA.

At activity 214, an optional second anneal process is performed. The second anneal process can include performing the anneal process in a hydrogen or deuterium containing environment so as to expose the surface of the channel layer 314, after performing the etching process in activity 212, to a hydrogen containing gas to help drive the hydrogen atoms into the channel layer 314 to further passivate the defects found therein. The annealing process can include a high pressure anneal process (e.g., ˜5 ATM), a spike anneal process or other similar process that is able to drive the hydrogen (H) atoms into the channel layer 314. Typically, the concentration of hydrogen atoms in the channel layer 314 after performing the second anneal process will be greater than 1×10¹⁴ atoms/cm³, or even greater than 1×10¹⁵ atoms/cm³.

At activity 216, in some embodiments, a memory hole fill process is performed where a filler layer 318 is deposited in each of the memory holes 310 in a portion of the 3D NAND memory structure 100 on the channel layer 314. For example, the filler layer 318 may be formed of silicon dioxide (SiO₂), aluminum oxide (Al₂O₃), or silicon nitride (Si₃N₄). In some embodiments, the deposition of the filler layer 318 may fill the remainder of the memory hole 310 in the 3D NAND memory structure 100. The filler layer 318, such as an oxide layer, can be deposited using any suitable deposition processes and/or apparatus. For example, physical vapor deposition (PVD), atomic layer deposition (ALD), plasma enhanced ALD (PEALD), chemical vapor deposition (CVD) or plasma enhanced chemical vapor deposition (PECVD) process may be used to deposit the channel layer 314 and second channel layer, the ONO layer stack 312, and the filler layer 318. Alternatively or additionally, a stand-alone apparatus or a cluster tool can be used to perform an atomic layer deposition (ALD) process. Exemplary apparatus that can be configured for performing the above process include, for example, the OLYMPIA line of ALD apparatus, available from Applied Materials, Inc.

At activity 218, a mold pull back process is performed to remove the dummy nitride layers 302, as shown in FIG. 3H. Subsequently, a word line layer 115 (shown in FIG. 1) is formed in place of the removed dummy nitride layer 302. In some of the subsequent steps, a drain region 128 (shown in FIG. 1) is formed over the plurality of the alternating layers 125. In some embodiments, at least a portion of the channel structure 117 formed within each of the memory holes 310 are coupled to a portion of the drain region 128 and a portion of the CSL 103. In some embodiments, a plurality of bit lines 118 (shown in FIG. 1) may be deposited on top of the memory holes 310 in the 3D NAND memory structure 100. As a result of the deposition of the plurality of bit lines 118, the channel layer 314, and the filler layer 318 may contact a drain region 128 (e.g., N+ drain layer).

While the foregoing is directed to embodiments of the present disclosure, other and further embodiments of the disclosure may be devised without departing from the basic scope thereof, and the scope thereof is determined by the claims that follow.

We claim:

1. A three-dimensional memory device, comprising:
a plurality of alternating layers formed over a surface of a substrate, wherein the alternating layers comprises a word line layer and an inter-word line dielectric layer that are stacked in a first direction;
an ONO layer stack disposed over the surface of each of a plurality of memory holes formed through the plurality of alternating layers, wherein the ONO layer stack extends in the first direction; and
a channel layer disposed over the ONO layer stack, the channel layer having a first end coupled to a source region, a second end coupled to a drain region, and extending through the plurality of alternating layers,
wherein the channel layer comprises a fluorine (F) concentration of greater than 1×10¹⁴ atoms/cm³ and a hydrogen (H) concertation of greater than 1×10¹⁴ atoms/cm³.

2. The three-dimensional memory device of claim 1, wherein the channel layer comprises polysilicon.

3. The three-dimensional memory device of claim 1, wherein the channel layer further comprises a fluorine (F) concentration >1×10¹⁵ atoms/cm³ and a hydrogen (H) concertation of >1×10¹⁵ atoms/cm³.

4. The three-dimensional memory device of claim 1, wherein the ONO stack comprises a first oxide layer over the surface of each of the plurality of memory holes through the plurality of alternating layers, a charge trap layer on the first oxide layer, and a second oxide layer on the charge trap layer.

5. The three-dimensional memory device of claim 4, wherein the charge trap layer comprises silicon nitride (Si₃N₄) or polycrystalline silicon (poly-Si).

6. A method of forming a three-dimensional memory device, comprising:
forming a channel structure within a plurality of openings formed through a plurality of alternating layers formed over a surface of a substrate, comprising:
forming a ONO layer stack over a surface of each of the plurality of openings; and
forming a polysilicon layer over a surface of the ONO layer stack;
forming a fluorine containing layer on the formed polysilicon layer;
annealing the substrate, wherein annealing the substrate causes fluorine atoms originally disposed in the fluorine containing layer to diffuse into the polysilicon layer;
selectively removing the fluorine containing layer; and
annealing the substrate in a hydrogen containing environment,
wherein annealing the substrate causes hydrogen atoms from the hydrogen containing environment to diffuse into the polysilicon layer; and
forming a drain region layer over the plurality of alternating layers, wherein at least a portion of the formed channel structure is coupled to a portion of the drain region layer and coupled to a portion of a source region layer of the three-dimensional memory device.

7. The method of claim 6, wherein forming the channel structure further comprises forming a filler layer over a surface of the polysilicon layer after the fluorine containing layer is selectively removed.

8. The method of claim 7, wherein the plurality of alternating layers comprise:
a word line layer and an inter-word line dielectric layer that are stacked in a first direction over the source region layer that is disposed over the surface of the substrate; and
the plurality of openings extend in the first direction from the source region layer and through the plurality of alternating layers.

9. The method of claim 8, wherein the annealing of the substrate comprises a high pressure anneal process.

10. The method of claim 7, wherein fluorine and hydrogen passivate grain boundaries and interface traps in the polysilicon layer.

11. A method of forming a channel structure of a three-dimensional memory device, comprising:
performing a mold deposition process to form a plurality of alternating layers of dummy nitride layers and inter-word line dielectric layers over a surface of a substrate;
performing a memory hole etch process to etch a plurality of memory holes through the plurality of alternating layers;
performing a memory hole channel layer deposition process to form a channel structure within each of the plurality of memory holes, the memory hole channel layer deposition process comprising:
depositing an oxide-nitride-oxide (ONO) layer stack over the surface of each of the memory holes, the ONO layer stack comprising a first oxide layer on inner surfaces of each of the plurality of memory holes, a charge trap layer on the first oxide layer, and a second oxide layer on the charge trap layer; and
depositing a channel layer on the second oxide layer;
performing a fluorine containing layer deposition process to form a fluorine (F) containing layer over the channel layer;
performing a first anneal process to diffuse mobile fluorine (F) atoms in the fluorine (F) containing layer; and
performing an etching process to selectively remove the fluorine (F) containing layer.

12. The method of claim 11, wherein the channel layer comprises polysilicon.

13. The method of claim 11, wherein
the fluorine containing layer deposition process comprises forming a fluorine (F)-containing amorphous silicon layer on the channel layer.

14. The method of claim 11, wherein
the first anneal process comprises a spike anneal process, and
concentration of fluorine atoms in the channel layer after the first anneal process is greater than 1×10¹⁴/cm³.

15. The method of claim 11, further comprising:
subsequent to the etching process, performing a second anneal process to drive hydrogen atoms from hydrogen or deuterium containing environment to diffuse into the channel layer.

16. The method of claim 15, wherein
the second anneal process comprises a spike anneal process, and
concentration of hydrogen atoms in the channel layer after the second anneal process is greater than 1×10¹⁴/cm³.

17. The method of claim 11, further comprising:
subsequent to the etching process, performing a memory hole fill process to deposit a filler layer in each of the plurality of memory holes.

18. The method of claim 17, wherein the filler layer comprises silicon dioxide (SiO₂), aluminum oxide (Al₂O₃), or silicon nitride (Si₃N₄).

19. The method of claim 17, further comprising:
subsequent to the memory hole fill process, performing a mold pull back process to remove the dummy nitride layers of the plurality of alternating layers and deposit word line layers.

20. The method of claim 19, further comprising:
forming a drain region layer over the plurality of alternating layers, wherein at least a portion of the formed channel structure is coupled to a portion of the drain region layer and coupled to a portion of a source region layer of the three-dimensional memory device.
